(19) United States
(12) Patent Application Publication
(10) Pub. No.: US 2026/0297747 A1
(43) Pub. Date: Oct. 1, 2026

(54) ATOMIC LAYER DEPOSITION REACTION CHAMBER AND AN ATOMIC LAYER DEPOSITION REACTOR

(71) Applicant: BENEQ OY, Espoo (FI)

(72) Inventors: Markus BOSUND, Espoo (FI); Pekka SOININEN, Espoo (FI); Esko KARPPANEN, Espoo (FI); Pasi MERILÄINEN, Espoo (FI)

(21) Appl. No.: 19/695,556

(22) Filed: Jun. 2, 2026

Related U.S. Application Data
(62) Division of application No. 18/681,894, filed on Aug. 12, 2022, now abandoned.

(30) Foreign Application Priority Data
Aug. 13, 2021 (FI) 20215853

(51) Int. Cl. C23C 16/455; C23C 16/458

(52) U.S. Cl. CPC C23C 16/45551; C23C 16/45502; C23C 16/45563; C23C 16/4583

(57) ABSTRACT

An atomic layer deposition reaction chamber includes first and second ends, first and second side walls extending between the first and second ends, a longitudinal central axis, and a width central axis perpendicular to the longitudinal central axis. A gas inlet and a gas outlet are spaced apart along the longitudinal central axis. The reaction chamber includes an increasing width area between the first end and the width central axis, a decreasing width area between the width central axis and the second end, and a constant width area between the increasing width area and the decreasing width area. A width of the reaction chamber increases in the increasing width area, decreases in the decreasing width area, and remains constant in the constant width area. A length of the reaction chamber is greater than a width of the reaction chamber along the width central axis.

### CROSS-REFERENCE TO RELATED APPLICATIONS

This application is a division of U.S. Patent Application No. 18/681,894, filed February 7, 2024, the entire contents of which are hereby incorporated herein by reference.

### FIELD

The present disclosure relates to an atomic layer deposition reaction chamber and more particularly to a reaction chamber.

### BACKGROUND

The atomic layer deposition (ALD) process and one ALD cycle includes four gas exchanges to produce one monolayer. Therefore, ALD cycle time is a limiting factor for the growth rate. Further, the cycle time depends on how fast pulse chemistry can be distributed on a substrate surface and how fast the residual gases are purged from the surface. For good gas exchange and good quality, a uniform gas flow across the substrate surface should be achieved. If gas flow across the substrate is non-uniform, it means that the gas flow is different at different parts of the substrate surface. Due to non-uniform gas flow the gas doses during one ALD cycle need to be increased and the cycle time and residence time of the gas in the reaction chamber need to be increased. This causes slow process times and decrease in efficiency and also poor material efficiency.

In some prior reaction chambers and ALD reactors, uniform gas flow, short cycle time, and good material efficiency may be compromised. This is especially the case when round-shaped substrates, such as silicon wafers, are processed. When round-shaped substrates are processed, gases are exchanged more easily near the edges of the round substrate surface than in the middle of the round substrate.

FIG. 2 shows a prior art atomic layer deposition chamber 20 of an atomic layer deposition reactor 10. The reaction chambers 20 of FIG. 2 have a first end 24 and a second end 26 on opposite sides of the reaction chamber 20. The reaction chamber 20 further comprises a gas inlet 30 in the vicinity of the first end 24 and a gas outlet 40 in the vicinity of the second end 26. The gas inlet 30 and the gas outlet 40 are disposed in the bottom wall 23 of the reaction chamber 20. There is a substrate holder 50 arranged between the gas inlet 30 and the gas outlet 40 for supporting one or more round-shaped substrates. The gases are supplied from the gas inlet 30 and discharged from the gas outlet 40 such that the gases flow in the reaction chamber 20 from the gas inlet 30 to the gas outlet 40. The gas flow between the gas inlet 30 and the gas outlet 40 flows across the surfaces of the one or more round-shaped substrates.

In the prior art reaction chamber 20, as in FIG. 2, the reactor walls are straight in a direction between the first end 24 and the second end 26, or in a direction between the gas inlet 30 and the gas outlet 40. The gas molecules of the gas flow have two flow paths from the gas inlet 30 to the gas outlet, a first flow path A and a second flow path B. The gas supplied from the gas inlet 30 tends to take the flow path A because the conductance of flow path A is different from (e.g., smaller than) the conductance of flow path B. Therefore, a majority of gas molecules take the flow path A which causes a bypass effect as the gas molecules flow from vicinity of the side walls of the reaction chamber and the edge area of the round substrate. A smaller amount of gas molecules flows via the flow path B. This same bypass effect occurs with circular reaction chambers. The bypass effect is especially problematic for round substrates as only a minor portion of the substrate surface is close to the side walls of the reaction chamber between the gas inlet 30 and the gas outlet 40. Further, in the reaction chamber of FIG. 2, there are gas pockets which slow down gas flow in the reaction chamber 20.

The bypass effect of some prior reaction chambers 20 may cause poor precursor gas economy as a large proportion of the precursor molecules bypass the substrate surface to be coated and flow directly into the gas outlet 40. Thus, an underdose of precursor gases occurs in the middle parts of the reaction chamber 20 due to the fact that only a small proportion of precursor molecules follow the flow path B. The underdose causes further uniformity issues on the substrate surface and in the coating provided on the substrate surface. When the underdose in the middle parts of the reaction chamber 20 is compensated for with a high overdose of supplied precursors to the reaction chamber 20, purging the reaction chamber 20 takes longer time as there are precursor molecules to be purged. Thus, the ALD cycle time is prolonged and efficiency of the process is compromised as well as material efficiency.

### SUMMARY

The present disclosure provides an atomic layer deposition reaction chamber and an atomic layer deposition reactor. In some examples, the reaction chamber may reduce bypass flow, improve gas flow uniformity, reduce purge time, or improve material efficiency.

In some examples, an atomic layer deposition reaction chamber comprises a first end, a second end opposite the first end, and a longitudinal central axis extending between the first end and the second end and a length between the first end and the second end in the direction of the longitudinal central axis. The reaction chamber further comprises a first side wall extending between the first end and the second end, and a second side wall opposite the first side wall and extending between the first end and the second end, the first side wall and the second side wall defining a width of the reaction chamber between the first end and the second end, and the reaction chamber having a width central axis extending between the first side wall and the second side wall and perpendicularly to the longitudinal central axis. The reaction chamber also comprises a gas inlet for supplying gases into the reaction chamber and a gas outlet for discharging gases from the reaction chamber. The gas inlet and the gas outlet are spaced apart along the longitudinal central axis of the reaction chamber.

In some examples, the reaction chamber has an increasing width along the longitudinal central axis in the direction from the first end towards the width central axis. The reaction chamber also has a decreasing width along the longitudinal central axis in the direction from the width central axis towards the second end. The length of the reaction chamber is greater than the width of the reaction chamber along the width central axis.

The reaction chamber having increasing width and decreasing width in the direction between the first end and the second end enables arranging the side walls at a very short distance from the substrate. Further, the increasing and decreasing width may enable the side walls of the reaction chamber to partly follow the outer edges of round substrates. Furthermore, the oval or oval-like shape provided by the greater length than the width enables forming sufficient distance between the gas inlet and the substrates in the direction between the first and second ends such that precursor gas molecules have adequate time and space to spread before meeting the substrates. Thus, the bypass effect is minimized.

In one embodiment, the reaction chamber has the increasing width along the longitudinal central axis from the first end to the width central axis and the decreasing width along the longitudinal central axis from the width central axis to the second end.

Therefore, the width of the reaction chamber increases from the first end to the width central axis and decreases from the width central axis to the second end. This provides efficient gas flow and minimal bypass effect.

In another embodiment, the reaction chamber comprises an increasing width area between the first end and the width central axis, the increasing width area extending from the first end to the width central axis and having the increasing width along the longitudinal central axis from the first end to the width central axis. The reaction chamber further comprises a decreasing width area between the width central axis and the second end, the decreasing width area extending from the width central axis to the second end and having the decreasing width along the longitudinal central axis from the width central axis to the second end.

The increasing width area and the decreasing width area provide an oval or oval-like reaction chamber enabling good precursor flow uniformity and fast flow between the first end and the second, or between the gas inlet and the gas outlet.

In one embodiment, the first and second side walls comprise an increasing width wall part extending from the first end to the width central axis. The increasing width wall parts are planar wall parts or curved wall parts. The first and second side walls comprise a decreasing width wall part extending from the width central axis to the second end. The decreasing width wall parts are planar wall parts or curved wall parts.

Straight increasing and decreasing wall parts provide simple reaction chamber structure.

Curved increasing and decreasing wall parts provide reaction chamber shape conforming more closely the shape of a round substrate.

In another embodiment, the first and second side walls comprise an increasing width wall part in the increasing width area. The increasing width wall parts are planar wall parts or curved wall parts. The first and second side walls comprise a decreasing width wall part in the decreasing width area. The decreasing width wall parts are planar wall parts or curved wall parts.

Straight increasing and decreasing width areas provide simple reaction chamber structure.

Curved increasing and decreasing width areas provide reaction chamber shape conforming more closely the shape of a round substrate.

In one embodiment, the reaction chamber comprises an increasing width area, a decreasing width area, and a constant width area between the increasing width area and the decreasing width area. The width of the reaction chamber in the constant width area is constant along the longitudinal central axis.

The constant width between the increasing width and the decreasing width may enhance uniform and stable gas flow. Further, a substrate holder may be more easily arranged into the reaction chamber.

In another embodiment, the reaction chamber comprises an increasing width area between the first end and the width central axis. The increasing width area comprises the increasing width along the longitudinal central axis in the direction from the first end towards the width central axis. The reaction chamber comprises a decreasing width area provided between the width central axis and the second end. The decreasing width area comprises the decreasing width along the longitudinal central axis in the direction from the width central axis towards the second end. The reaction chamber further comprises a constant width area provided between the increasing width area and the decreasing width area.

The constant width area between the increasing width area and the decreasing width area may enhance providing more uniform and stable gas flow. Further, the constant width area provides a structurally suitable location for a substrate holder.

In one embodiment, the reaction chamber comprises a substrate holder arranged inside the reaction chamber between the first end and the second end and between the gas inlet and the gas outlet.

In another embodiment, the reaction chamber comprises a substrate holder arranged inside the reaction chamber between the first end and the second end and between the gas inlet and the gas outlet. The substrate holder is arranged symmetrically inside the reaction chamber with respect to the intersection of the longitudinal central axis and the width central axis.

Accordingly, the substrate holder takes advantage of the increasing and decreasing width areas with fast and uniform gas flow through the substrate holder.

In one embodiment, the substrate holder is arranged to extend in the direction of the longitudinal central axis in the increasing width area and in the decreasing width area.

In another embodiment, the substrate holder is arranged to extend in the direction of the longitudinal central axis from the increasing width area to the decreasing width area.

Therefore, the substrates may also be arranged to extend to the increasing width area and to the decreasing width area such that the side walls of the reaction chamber are provided close to the edges of the substrate.

In a further embodiment, the substrate holder is arranged to extend in the direction of the longitudinal central axis in the increasing width area, in the decreasing width area and in the constant width area.

In a further alternative embodiment, the substrate holder is arranged to extend in the direction of the longitudinal central axis from the increasing width area to the decreasing width area via the constant width area.

Therefore, the substrates may also be arranged to extend from the constant width area to the increasing width area and to the decreasing width area such that the side walls of the reaction chamber are provided close to the edges of the substrate also in a direction towards the gas inlet and the gas outlet.

In one embodiment, the substrate holder comprises in the direction of the longitudinal central axis a front end opposite the first end and a back end opposite the second end. The substrate holder defines a substrate zone inside the reaction chamber between the front end and the back end in the direction of the longitudinal central axis. The reaction chamber also comprises a supply zone extending in the direction of the longitudinal central axis between the first end of the reaction chamber and the front end of the substrate holder. The gas inlet is disposed in the supply zone. The reaction chamber further comprises a discharge zone extending in the direction of the longitudinal central axis between the second end of the reaction chamber and the back end of the substrate holder. The gas outlet is disposed in the discharge zone. The increasing width area extends in the direction of the longitudinal central axis from the supply zone to the substrate zone, and the decreasing width area extends in the direction of the longitudinal central axis from the discharge zone to the substrate zone.

Accordingly, the substrate area overlaps the increasing width area and the decreasing width area in the direction of the longitudinal central axis. Thus, the side walls of the reaction chamber are close to edges of the substrate in the substrate area.

In one embodiment, the constant width area is disposed within the substrate zone in the direction of the longitudinal central axis.

In another embodiment, the constant width area is disposed within the substrate zone in the direction of the longitudinal central axis, and the substrate zone has a greater length than the constant width area in the direction of the longitudinal central axis.

Thus, a uniform gas flow is achieved in the substrate area.

In one embodiment, a first distance between the substrate holder and the first or second side wall along the width central axis is smaller than a second distance between the substrate holder and the first or second end along the longitudinal central axis.

Therefore, the substrates are close to the side walls of the reaction chamber and greater space and distance between the gas inlet / gas outlet and the substrate holder may be provided.

In one embodiment, the substrate holder is arranged to support one or more circular substrates or circular semiconductor wafers.

The reaction chamber of the present disclosure is especially suitable for round substrates as the increasing and decreasing width enables minimizing distance between the round substrate and the side walls of the reaction chamber.

In some embodiments, the reaction chamber comprises a bottom wall, a top wall, the first and second side walls and the first and second ends. The first and second side walls and the first and second ends extend between the bottom wall and the top wall.

In one embodiment, the gas inlet and the gas outlet are disposed in the bottom wall. This enables simple reaction chamber construction.

In another embodiment, the gas inlet is disposed in the bottom wall in the vicinity of the first end and the gas outlet is disposed in the bottom wall in the vicinity of the second end. This provides great distance between the gas inlet / gas outlet and the substrate holder or substrate together with simple reaction chamber construction.

In a further embodiment, the gas inlet is disposed in the first end and the gas outlet is disposed in the second end. This provides great distance between the gas inlet / gas outlet and the substrate holder or the substrate.

The present disclosure further relates to an atomic layer deposition reactor comprising a vacuum chamber and a reaction chamber arranged inside the vacuum chamber. The reaction chamber comprises a first end, a second end opposite the first end, a longitudinal central axis extending between the first end and the second end, and a length between the first end and the second end along the longitudinal central axis. The reaction chamber also comprises a first side wall and the second side wall extending between the first end and the second end, a width central axis extending perpendicularly to the longitudinal central axis between the first and second side walls, and a width between the first and second side walls in the direction of the width central axis. The reaction chamber further comprises a gas inlet for supplying gases into the reaction chamber, and a gas outlet for discharging gases from the reaction chamber. The gas inlet and the gas outlet are spaced apart on opposite sides of the width central axis in the direction of the longitudinal central axis.

In some examples, the first and second side walls of the reaction chamber are arranged to define an increasing width along the longitudinal central axis in the direction from the gas inlet towards the width central axis and a decreasing width along the longitudinal central axis in the direction from the width central axis towards the gas outlet, and the length of the reaction chamber is greater than the width of the reaction chamber along the width central axis.

The increasing width and the decreasing width in the direction between the gas inlet and the gas outlet enable arranging the side walls at a very short distance from the substrate, especially outer edges of round substrates. Furthermore, the oval or oval-like shape provided by the greater length than the width enables forming sufficient distance between the gas inlet and the substrates in the direction of the longitudinal central axis such that precursor gas molecules have adequate time and space to spread before meeting the substrates. Thus, the bypass effect is minimized.

In one embodiment, the reactor comprises at least one gas inlet connection extending from outside the vacuum chamber to the reaction chamber and being connected to the gas inlet for supplying gas into the reaction chamber from outside the vacuum chamber, and at least one gas outlet connection extending from outside the vacuum chamber to the reaction chamber and being connected to the gas outlet for discharging gas from the reaction chamber to outside the vacuum chamber.

Thus, the gases are supplied to and discharged from the reaction chamber from outside the vacuum chamber. A controlled and secure processing environment is generated inside the reaction chamber.

In one embodiment, the reaction chamber comprises an increasing width area, a decreasing width area, and a constant width area between the increasing width area and the decreasing width area. The width of the reaction chamber in the increasing width area increases along the longitudinal central axis in a direction from the gas inlet toward the width central axis. The width of the reaction chamber in the decreasing width area decreases along the longitudinal central axis in a direction from the width central axis toward the gas outlet. The width of the reaction chamber in the constant width area is constant along the longitudinal central axis.

The reaction chamber of the reactor may be a reaction chamber as disclosed above.

In some examples, the increasing width and the decreasing width in the direction between the gas inlet and the gas outlet, and in the direction of the longitudinal central axis, may enable arranging the side walls at a very short distance from the substrate, especially outer edges of round substrates. Furthermore, the oval or oval-like shape provided by the greater length than the width enables forming sufficient distance between the gas inlet and the substrates in the direction of the longitudinal central axis such that precursor gas molecules have adequate time and space to spread before meeting the substrates. Thus, the bypass effect is minimized. At the same time good flow dynamics without gas pockets in the reaction chamber may be achieved such that considerable overdose does not need to be utilized and purging the reaction chamber may be carried out in a short time.

### BRIEF DESCRIPTION OF THE DRAWINGS

Examples of the disclosure are described with reference to the accompanying drawings, in which

FIG. 1 shows a schematic view of an atomic layer deposition reactor;

FIG. 2 shows schematically a prior art atomic layer deposition reaction chamber;

FIGS. 3 to 8 show schematically one embodiment of an atomic layer deposition reaction chamber according to the present disclosure;

FIGS. 9 to 12 show schematically another embodiment of an atomic layer deposition reaction chamber according to the present disclosure;

FIGS. 13 and 14 show schematically a further embodiment of an atomic layer deposition reaction chamber according to the present disclosure;

FIGS. 15 to 16 show schematically yet another embodiment of an atomic layer deposition reaction chamber according to the present disclosure;

FIG. 17 shows schematically an alternative embodiment of an atomic layer deposition reaction chamber according to the present disclosure;

FIGS. 18 to 19 show schematically modifications to atomic layer deposition reaction chambers according to the present disclosure; and

FIG. 20 shows schematically a modification of the embodiment of FIGS. 13 and 14.

### DETAILED DESCRIPTION

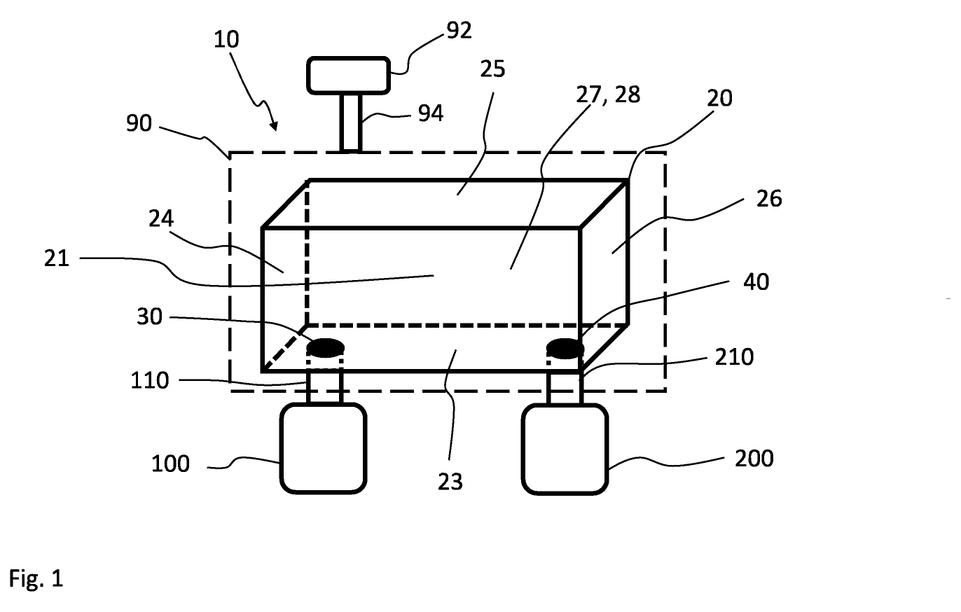

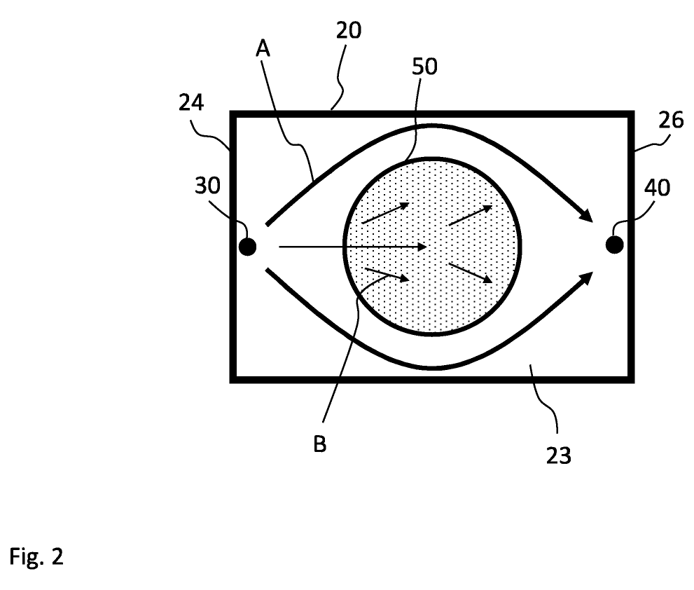

FIG. 1 shows schematically an atomic layer deposition reactor 10. The reactor 10 comprises a vacuum chamber 90. The vacuum chamber 90 is constructed to withstand reduced pressure. A vacuum device 92 is connected to the vacuum chamber 90 and arranged to provide vacuum or under pressure inside the vacuum chamber 90. The vacuum device 92 is connected to the vacuum chamber 90 with a vacuum connection 94.

The vacuum device 92 is a vacuum pump or the like device capable of providing vacuum or under pressure inside the vacuum chamber 90. The vacuum device 92 is arranged outside the vacuum chamber 90.

The reactor 10 further comprises a reaction chamber 20 arranged inside the vacuum chamber 90. Substrates are processed inside the reaction chamber 20.

The reaction chamber 20 comprises a first end 24, a second end 26 opposite the first end 24, a first side wall 27 and a second side wall 28 extending between the first end 24 and the second end 26. The reaction chamber 20 has a length between the first end 24 and the second end 26, and a width between the first side wall 27 and the second side wall 28.

The reaction chamber 20 further comprises a bottom wall 23 and a top wall 25. The first end 24, the second end 26, the first side wall 27 and the second side wall 28 extend between the bottom wall 23 and the top wall 25.

The reaction chamber 20 has a reaction space 21 defined by the walls 23, 25, 24, 26, 27, 28.

The reaction chamber 20 is provided with a gas inlet 30 via which precursor gases, purge gases or the like are supplied inside the reaction chamber 20. In some embodiments, there are one or more gas inlets 30.

The gas inlet 30 is connected to one or more gas sources 100, such as precursor gas source and purge gas source. The gas sources 100 are arranged outside the reaction chamber 20 and outside the vacuum chamber 90. The gas sources 100 are connected to the gas inlet 30 for supplying gases into the reaction chamber 20. Thus, the gases are supplied into the reaction chamber 20 from outside of the vacuum chamber 90. The gas sources 100 are connected to the gas inlet 30 with a gas supply connection 110. The gas supply connection 110 extends from the gas sources 100 and from outside the vacuum chamber 90 to the reaction chamber 20 and to the gas inlet 30. The gas source 100 may be gas bottle or the like.

The reaction chamber 20 is also provided with a gas outlet 40 via which precursor gases, purge gases or the like are discharged from inside of the reaction chamber 20. In some embodiments, there are one or more gas outlets 40.

The gas outlet 40 is connected to a discharge device 200. The discharge device 200 is arranged outside the reaction chamber 20 and outside the vacuum chamber 90. The discharge device 200 is connected to the gas outlet 40 for discharging gases from the reaction chamber 20. Thus, the gases are discharged from the reaction chamber 20 to outside of the vacuum chamber 90. The discharge device 200 is connected to the gas outlet 40 with a gas discharge connection 210. The gas discharge connection 210 extends from the discharge device 200 and from outside the vacuum chamber 90 to the reaction chamber 20 and to the gas outlet 40.

Accordingly, gases, such as precursor gases and purge gases, flow inside the reaction chamber 20 from the gas inlet 30 to the gas outlet 40. The substrates to be processed are arranged in the reaction chamber 20 between the gas inlet 30 and the gas outlet 40.

The reaction chamber 20 is further provided with a substrate holder to which one or more substrates are placed and supported for processing. The substrate holder is arranged between the gas inlet 30 and the gas outlet 40 such that gases flow through the substrate holder between the gas inlet 30 and the gas outlet 40 and expose surfaces of the substrate(s) to the gases.

The gas inlet 30 and the gas outlet 40 are disposed in the bottom wall 23 in the vicinity of the first end 24 and the second end 26, respectively.

Alternatively, the gas inlet 30 and the gas outlet 40 are disposed in the top wall 25 in the vicinity of the first end 24 and the second end 26, respectively.

In an alternative embodiment, the gas inlet 30 and the gas outlet 40 are disposed in the first end 24 and second end 26, respectively.

Accordingly, the gas inlet 30 and the gas outlet 40 are spaced apart from each other inside the reaction chamber 20, in the direction between the first end 24 and the second end 26. Thus, the substrates may be placed between the gas inlet 30 and the gas outlet 40.

In the present disclosure, the reaction chamber 20 has generally oval or oval-like shape. This means, that the length of the reaction chamber 20 between the first end 24 and the second end 26 is greater than the width, or greatest width, of the reaction chamber 20. Furthermore, the oval-like shape means that the width of the reaction chamber 20 increases at least along part of the length of the reaction chamber in the direction from the first end 24 towards the second end 26, and the width of the reaction chamber 20 increases at least along part of the length of the reaction chamber in the direction from the second end 26 towards the first end 24. Thus, the width of the reaction chamber 20 increases in the direction from the first end 24 and from the second 26 towards the center of the reaction chamber 20. The width of the reaction chamber 20 is defined by the side walls of the reaction chamber 20.

The oval or oval-like shape of the reaction chamber 20 is formed between the first end 24 and the second end 26. Alternatively, the oval or oval-like shape is formed at least between the gas inlet 30 and the gas outlet 40.

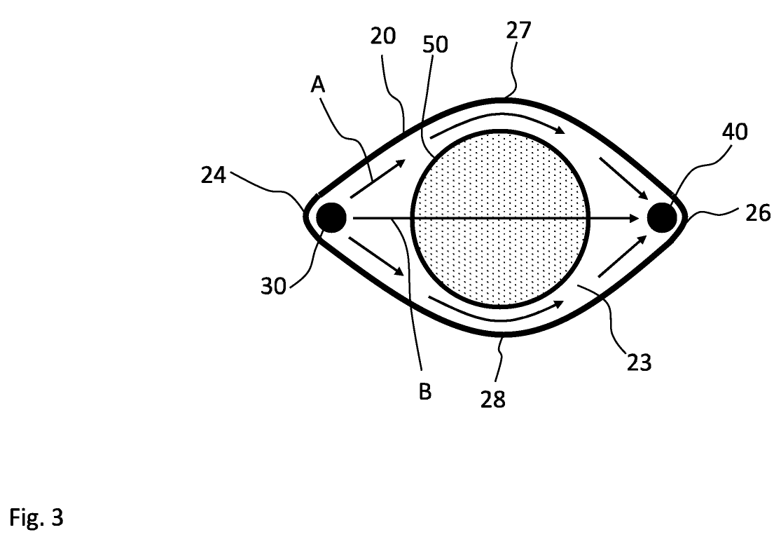

In the embodiments of FIGS. 3 to 19, the gas inlet 30 and the gas outlet 40 are disposed in the bottom wall 23 of the reaction chamber 20.

In alternative embodiments of the present disclosure, the gas inlet 30 and the gas outlet 40 are disposed in the top wall 25 of the reaction chamber 20 or in the first end 24 and the second end 26, respectively. The present disclosure is not limited to the exact location of the gas inlet 30 and the gas outlet 40.

Further, generally the reaction chamber 20 has a length L between the first end 24 and the second end 26. The reaction chamber 20 also comprises a longitudinal central axis X extending in the length direction of the reaction chamber 20, and in the direction between the first end 24 and the second end 26.

The first and second side walls 27, 28 define width W of the reaction chamber 20. In some examples, the width W of the reaction chamber 20 changes along the longitudinal central axis X. The reaction chamber 20 also comprises a width central axis Y extending in a direction between the first side wall 27 and the second side wall 28, and perpendicularly to the longitudinal central axis X.

The longitudinal central axis X extends in the length direction and the width central axis Y in the width direction of the reaction chamber.

The longitudinal central axis X divides the reaction chamber 20 in the length direction to two halves. The width central axis Y divides the reaction chamber 20 in the width direction to two halves.

FIG. 3 shows one embodiment of the reaction chamber 20 from above. The reaction chamber 20 has generally oval or oval-like shape.

The reaction chamber of FIG. 3 comprises the first end 24 and the second end 26, the first side wall 27 extending between the first end 24 and the second end 26 and the second side wall 28 opposite first side wall 27 and extending between the first end 24 and the second end 26.

In this embodiment, the gas inlet 30 and the gas outlet are disposed in the bottom wall 23.

There is a substrate holder 50 in the reaction chamber 20 arranged between the first end 24 and the second end 26, or more specifically between the gas inlet 30 and the gas outlet 40. The substrate holder 50 is arranged to hold one or more substrates, especially circular substrates during processing.

The arrows A and B in FIG. 3 represent gas flow from the gas inlet 30 to the gas outlet 40 in the reaction chamber 20. The oval or oval-like shape of the reaction chamber 20 causes a uniform flow between the gas inlet 30 and the gas outlet 40 across the reaction chamber 20, or the bottom wall 23. A more uniform amount of gas molecules take the longer flow path A along the side walls 27, 28 and the straight flow path B from the gas inlet 30 to the gas outlet 40.

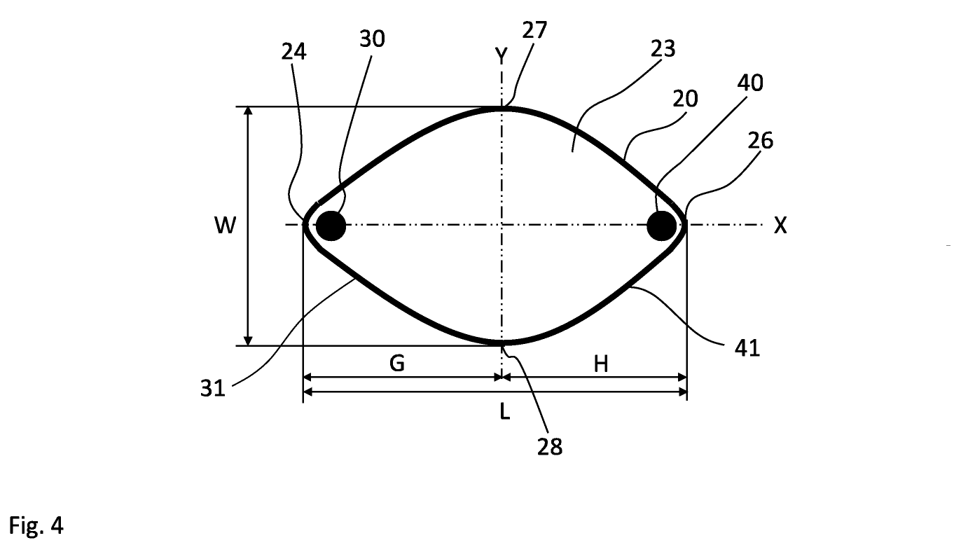

As shown in FIG. 4, the reaction chamber 20 comprises an increasing width W along the longitudinal central axis X from the first end 24 to the width central axis Y defined by the first and second side walls 27, 28. Further, the reaction chamber 20 has a decreasing width W along the longitudinal central axis X from the width central axis Y to the second end 26. Accordingly, the reaction chamber 20 has the greatest width at the width central axis Y along the longitudinal central axis X.

Therefore, the reaction chamber 20 comprises an increasing width area G between the first end 24 and the width central axis Y along the longitudinal central axis X from the first end 24 to the width central axis Y. Similarly, the reaction chamber 20 comprises a decreasing width area H between the width central axis Y and the second end 26 along the longitudinal central axis X, as shown in FIG. 4.

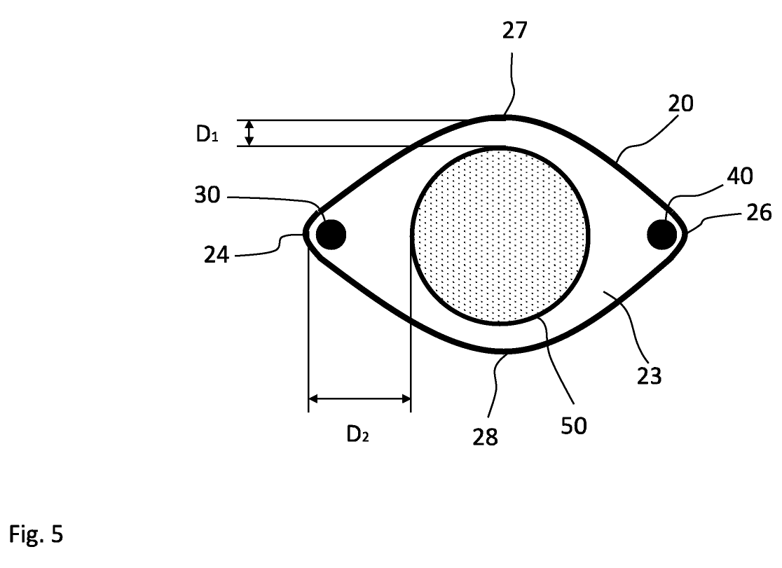

FIG. 5 shows the substrate holder 50 in the reaction chamber 20. The oval or oval-like shape of the reaction chamber 20 is arranged such that there is a first distance D₁ between the substrate holder 50 and the first and second side walls 27, 28 along the width central axis Y and a second distance D₂ between substrate holder 50 and the first and second end 24, 26 along the longitudinal central axis X. The oval or oval-like shape of the reaction chamber 20 is arranged such that the second distance D₂ is greater than the first distance D₁. This enables eliminating the bypass effect as well as increasing the size of the gas inlet 30 and the gas outlet 40 without increasing the first distance D₁.

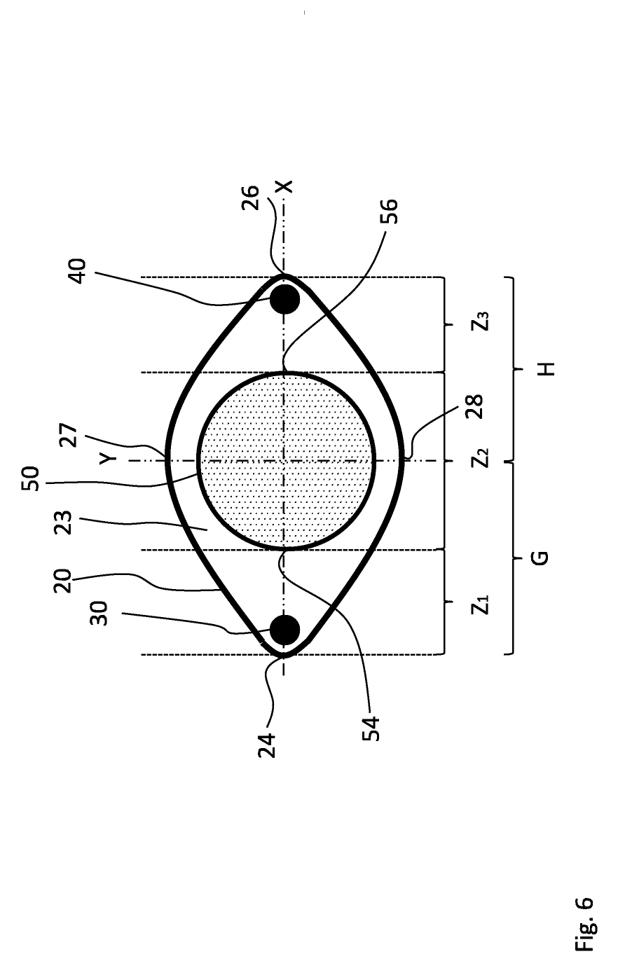

As shown in FIG. 6, the substrate holder 50 is arranged between the first and second ends 24, 26, and between the gas inlet 30 and the gas outlet 40.

Preferably, the substrate holder 50 is arranged in the center of the reaction chamber 20, in the cross section of the longitudinal central axis X and the width central axis Y.

The substrate holder 50 comprises in the direction of the longitudinal central axis X a front end 54 opposite the first end 24 and a back end 56 opposite the second end 26. The substrate holder 50 defines a substrate zone Z₂ inside the reaction chamber 20 between the front end 54 and the back end 56 in the direction of the longitudinal central axis X.

The reaction chamber 20 further comprises a supply zone Z₁ extending in the direction of the longitudinal central axis X between the first end 24 of the reaction chamber 20 and the front end 54 of the substrate holder 50. The gas inlet 30 is disposed in the supply zone Z₁. The reaction chamber 20 also comprises a discharge zone Z₃ extending in the direction of the longitudinal central axis X between the second end 26 of the reaction chamber 20 and the back end 56 of the substrate holder 50. The gas outlet 40 is disposed in the discharge zone Z₃.

The gas inlet 30 is arranged in the vicinity of the first end 24 and the gas outlet 40 is arranged in the vicinity of the second end 26.

Accordingly, the reaction chamber 20 comprises three zones along the longitudinal central axis X, the supply zone Z₁, the substrate zone Z₂ and the discharge zone Z₃. Gases are supplied from the gas inlet 30 in the supply zone Z₁, and discharged from the discharge zone Z₃ with the gas outlet 40, and the gases flow through the substrate zone Z₂.

As shown in FIG. 6, the increasing width area G extends in the direction of the longitudinal central axis X from the supply zone Z₁ to the substrate zone Z₂. Thus, the increasing width area G and the substrate zone Z₂ are partly overlapped. In the embodiment of FIG. 6, the increasing width area G and the substrate zone Z₂ are overlapped between the front end 54 of the substrate holder 50 and the width central axis Y. Similarly, the decreasing width area H extends in the direction of the longitudinal central axis X from the discharge zone Z₃ to the substrate zone Z₂. Thus, the decreasing width area H and the substrate zone Z₂ are partly overlapped. In the embodiment of FIG. 6, the decreasing width area H and the substrate zone Z₂ are overlapped between the width central axis Y and the back end 56 of the substrate holder 50.

In the embodiment of FIGS. 3 to 6, the first and second side walls 27, 28 of the reaction chamber 20 are curved. The first and second side walls 27, 28 are curved and outwardly convex between the first end 24 and the second end 26.

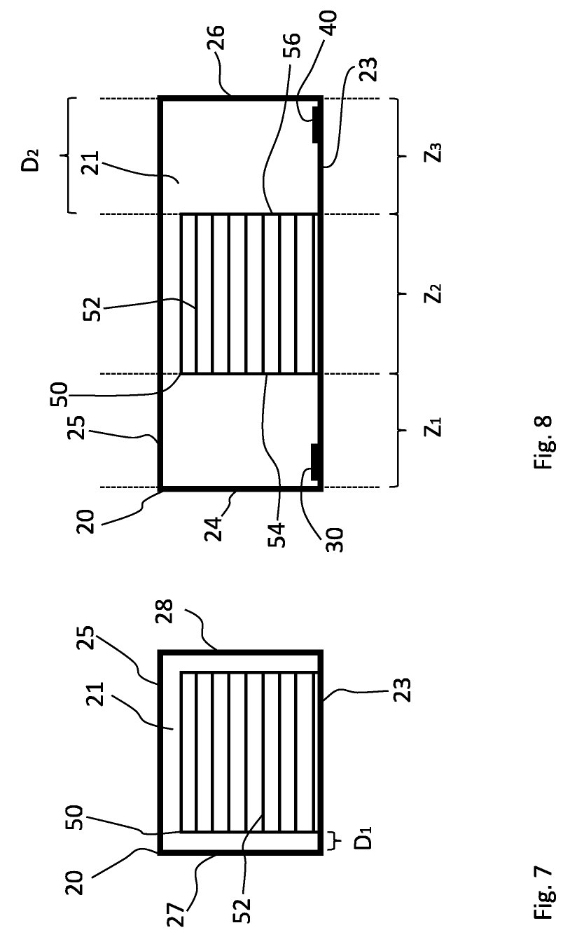

FIG. 7 shows a cross-sectional view of the reaction chamber 20 along the width central axis Y and from the direction of the first end 24. The substrate holder 50 comprises one or more substrate support surfaces or shelves 52 for supporting one or more substrates. The substrate holder 50 is arranged at the first distance D₁ from the first and second side walls 27, 28.

FIG. 8 shows another cross-sectional view of the reaction chamber 20 along the longitudinal central axis X and from the direction of the second side wall 28. The substrate holder 50 is arranged at the second distance D₂ from the first and second end 24, 26. The reaction chamber 20 further comprises the supply zone Z₁, substrate zone Z₂ and the discharge zone Z₃.

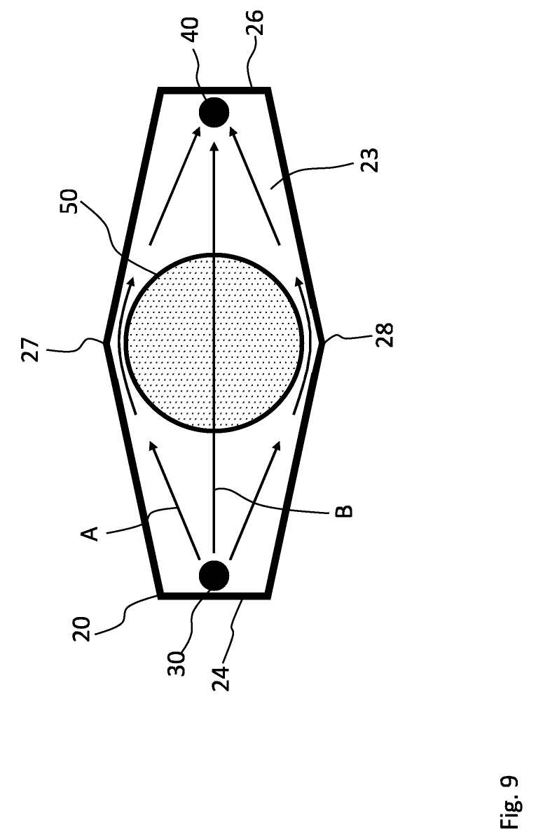

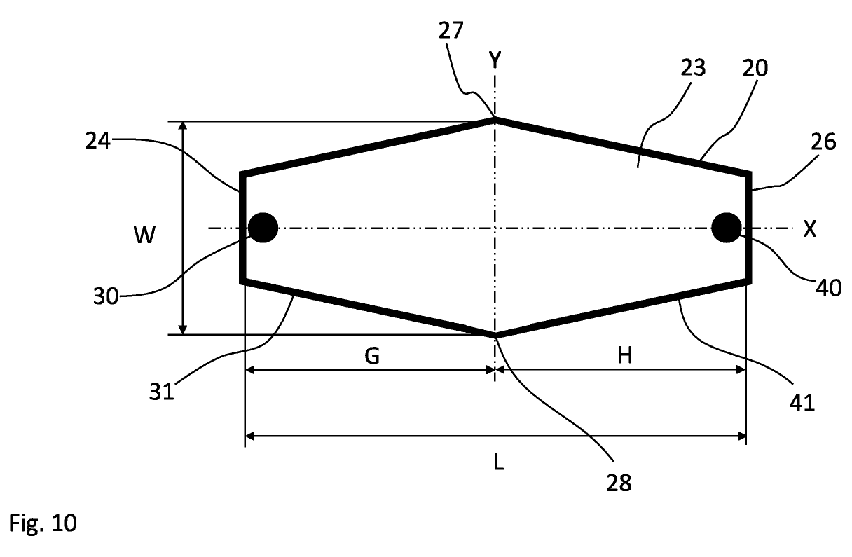

FIGS. 9 to 12 show an alternative embodiment, in which the first and second side walls 27, 28 are straight or planar. The first and second side walls 27, 28 comprise diverging wall portions 31 extending from the first end 24 to the width central axis Y. The first and second side walls 27, 28 further comprise converging wall portions 41 extending from the width central axis Y to the second end 26, as shown in FIG. 10.

The diverging wall portions 31 and the converging wall portions 41 are straight or planar.

The diverging wall portions 31 define the increasing width W along the longitudinal central axis X from the first end 24 to the width central axis Y. Further, the converging wall portions 41 define the decreasing width W along the longitudinal central axis X from the width central axis Y to the second end 26. Accordingly, the reaction chamber 20 has the greatest width at the width central axis Y along the longitudinal central axis X.

Therefore, the reaction chamber 20 comprises the increasing width area G between the first end 24 and the width central axis Y along the longitudinal central axis X from the first end 24 to the width central axis Y defined by the diverging wall portions 31. Similarly, the reaction chamber 20 comprises the decreasing width area H between the width central axis Y and the second end 26 along the longitudinal central axis X defined by the converging wall portion 41, as shown in FIG. 10.

The diverging wall portions 31 and the converging wall portions 41 provide the oval or oval-like shape of the reaction chamber 20.

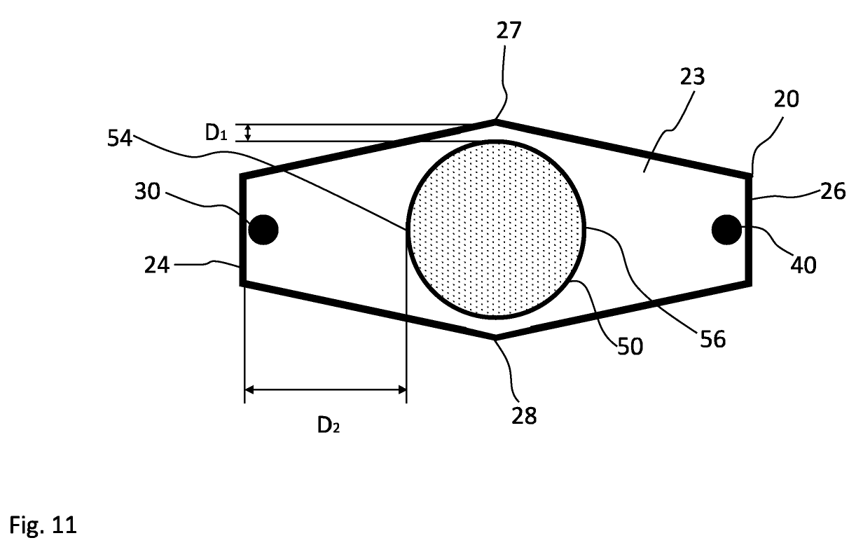

FIG. 11 shows the substrate holder 50 in the reaction chamber 20. The substrate holder 50 is arranged at first distance D₁ from the first and second side walls 27, 28 along the width central axis Y. The substrate holder 50 is further arranged at the second distance D₂ from the first and second end 24, 26 along the longitudinal central axis X. The oval or oval-like shape of the reaction chamber 20 is arranged such that the second distance D₂ is greater than the first distance D₁.

As shown in FIG. 9, the substrate holder 50 is arranged between the first and second ends 24, 26, and between the gas inlet 30 and the gas outlet 40.

Preferably, the substrate holder 50 is arranged in the center of the reaction chamber 20, in the cross section of the longitudinal central axis X and the width central axis Y.

The reaction chamber 20 further comprises the supply zone Z₁ extending in the direction of the longitudinal central axis X between the first end 24 of the reaction chamber 20 and the front end 54 of the substrate holder 50. The gas inlet 30 is disposed in the supply zone Z₁. The reaction chamber 20 also comprises the discharge zone Z₃ extending in the direction of the longitudinal central axis X between the second end 26 of the reaction chamber 20 and the back end 56 of the substrate holder 50. The gas outlet 40 is disposed in the discharge zone Z₃. The substrate zone Z₂ is located between the front end 54 and the back end 56 of the substrate holder 50.

The gas inlet 30 is arranged in the vicinity of the first end 24 and the gas outlet 40 is arranged in the vicinity of the second end 26.

Accordingly, the reaction chamber 20 comprises three zones along the longitudinal central axis X, the supply zone Z₁, the substrate zone Z₂ and the discharge zone Z₃. Gases are supplied from the gas inlet 30 in the supply zone Z₁, and discharged from the discharge zone Z₃ with the gas outlet 40, and the gases flow through the substrate zone Z₂.

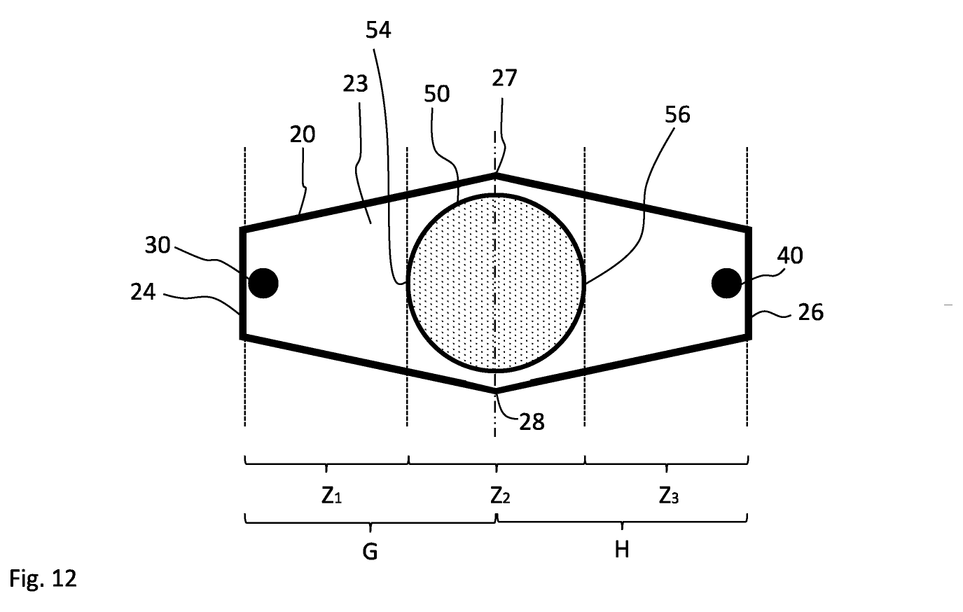

As shown in FIG. 12, the increasing width area G extends in the direction of the longitudinal central axis X from the supply zone Z₁ to the substrate zone Z₂. Thus, the increasing width area G and the substrate zone Z₂ are partly overlapped. In the embodiment of FIG. 12, the increasing width area G and the substrate zone Z₂ are overlapped between the front end 54 of the substrate holder 50 and the width central axis Y. Similarly, the decreasing width area H extends in the direction of the longitudinal central axis X from the discharge zone Z₃ to the substrate zone Z₂. Thus, the decreasing width area H and the substrate zone Z₂ are partly overlapped. In the embodiment of FIG. 6, the decreasing width area H and the substrate zone Z₂ are overlapped between the width central axis Y and the back end 56 of the substrate holder 50.

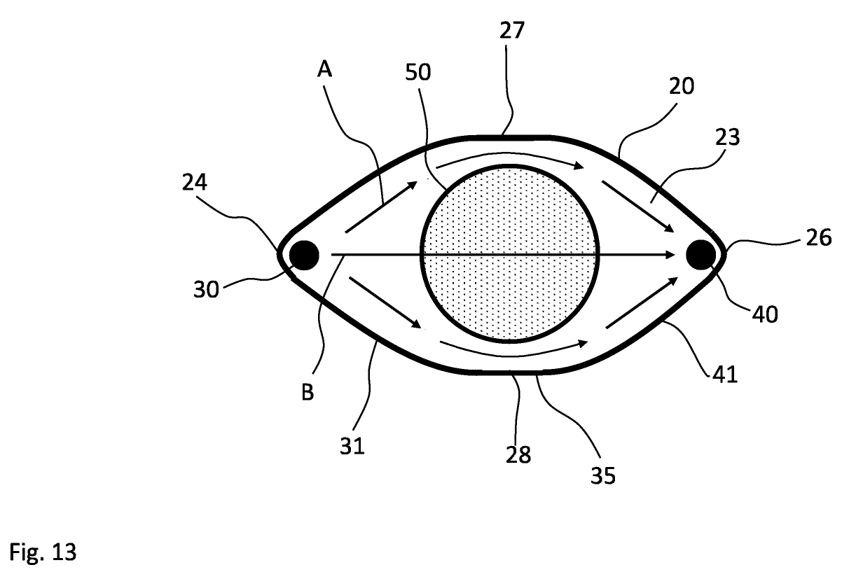

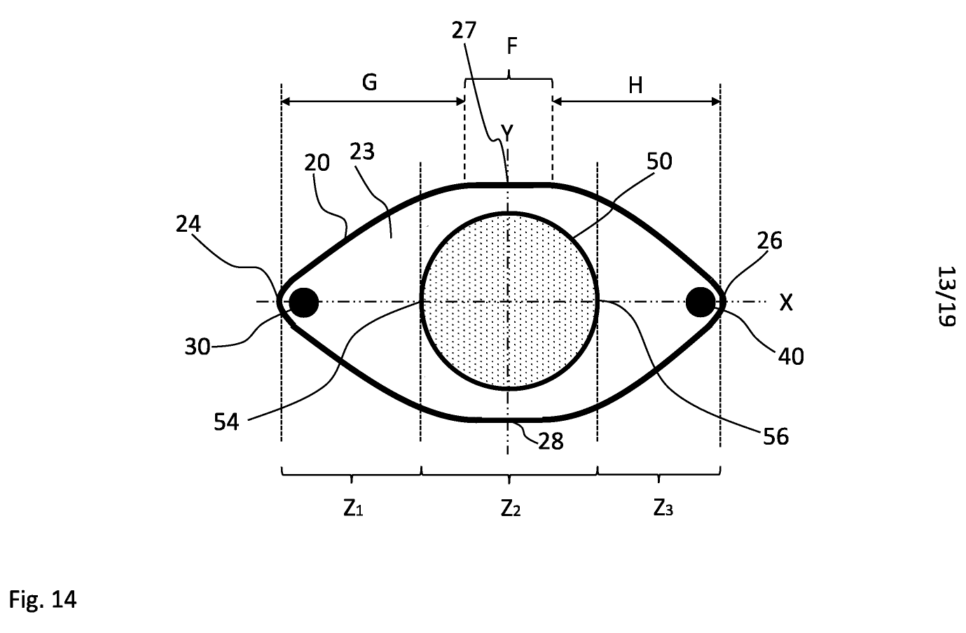

FIGS. 13 and 14 show a modification of the embodiment of FIGS. 3 to 6. In the embodiment of FIGS. 13 and 14, the reaction chamber 20 has generally oval or oval-like shape.

The reaction chamber of FIG. 13 comprises the first end 24 and the second end 26, the first side wall 27 extending between the first end 24 and the second end 26 and the second side wall 28 opposite first side wall 27 and extending between the first end 24 and the second end 26.

In this embodiment, the gas inlet 30 and the gas outlet are disposed in the bottom wall 23.

There is a substrate holder 50 in the reaction chamber 20 arranged between the first end 24 and the second end 26, or more specifically between the gas inlet 30 and the gas outlet 40. The substrate holder 50 is arranged to hold one or more substrates, especially circular substrates during processing.

In the embodiment of FIGS. 13 and 14, the first and second side walls 27, 28 comprise diverging wall portions 31 extending from the first end 24 towards the width central axis Y. The diverging wall portions 31 define the increasing width W of the reaction chamber 20.

The first and second side walls 27, 28 further comprise parallel wall portions 35 extending parallel to each other. The parallel wall portions 35 define constant width W along the longitudinal central axis X.

The parallel wall portions 35 extend in the direction of the longitudinal central axis X. The parallel wall portions 35 are straight or planar.

The parallel wall portions 35 extend from the diverging wall portions 31 towards the second end 26. The parallel wall portions 35 extend from the width central axis Y towards the first end 24 and the second end 26.

The first and second side walls 27, 28 comprise converging wall portions 41 extending from the parallel wall portions 35 to the second end 26. The converging wall portions 41 define the decreasing width W of the reaction chamber 20.

The diverging wall portions 31 and the converging wall portions 41 are curved wall portions. The diverging wall portions 31 and the converging wall portions 41 are curved and outwardly convex.

The reaction chamber 20 comprises the increasing width area G between the first end 24 and the parallel wall portions 35 along the longitudinal central axis X. The increasing width area G is defined by the diverging wall portions 31. The reaction chamber 20 further comprises a constant width area F extending from the increasing width area G towards the second end 26 along the longitudinal central axis X. The constant width area F is defined by the parallel wall portions 35. Further, the reaction chamber 20 comprises the decreasing width area H between the constant width area F and the second end 26 along the longitudinal central axis X, as shown in FIG. 14.

The constant width area F is arranged between the increasing width area G and the decreasing width area H.

Also, in this embodiment, the substrate holder 50 is at the first distance D₁ from the first and second side walls 27, 28 and at the second distance D₂ from the first and second end 24, 26. The oval or oval-like shape of the reaction chamber 20 is arranged such that the second distance D₂ is greater than the first distance D₁.

As shown in FIG. 14, the constant width area F is provided in the center of the reaction chamber 20 and it extends from the width central axis Y towards the first and second ends 24, 26.

The substrate holder 50 is arranged between the first and second ends 24, 26, and between the gas inlet 30 and the gas outlet 40.

Preferably, the substrate holder 50 is arranged in the center of the reaction chamber 20, in the cross section of the longitudinal central axis X and the width central axis Y.

The reaction chamber 20 comprises the supply zone Z₁, the substrate zone Z₂ and the discharge zone Z₃.

As shown in FIG. 14, the increasing width area G extends in the direction of the longitudinal central axis X from the supply zone Z₁ to the substrate zone Z₂. Thus, the increasing width area G and the substrate zone Z₂ are partly overlapped. In the embodiment of FIG. 14, the increasing width area G and the substrate zone Z₂ are overlapped between the front end 54 of the substrate holder 50 and the constant width area F. Similarly, the decreasing width area H extends in the direction of the longitudinal central axis X from the discharge zone Z₃ to the substrate zone Z₂. Thus, the decreasing width area H and the substrate zone Z₂ are partly overlapped. In the embodiment of FIG. 14, the decreasing width area H and the substrate zone Z₂ are overlapped between the constant width area F and the back end 56 of the substrate holder 50.

Furthermore, the constant width area F is provided within the substrate zone Z₂ in the direction of the longitudinal central axis X.

Accordingly, the constant width area F is provided within the substrate zone Z₂ in the direction of the longitudinal central axis X, and the substrate zone Z₂ has greater length than constant width area F in the direction of the longitudinal central axis X.

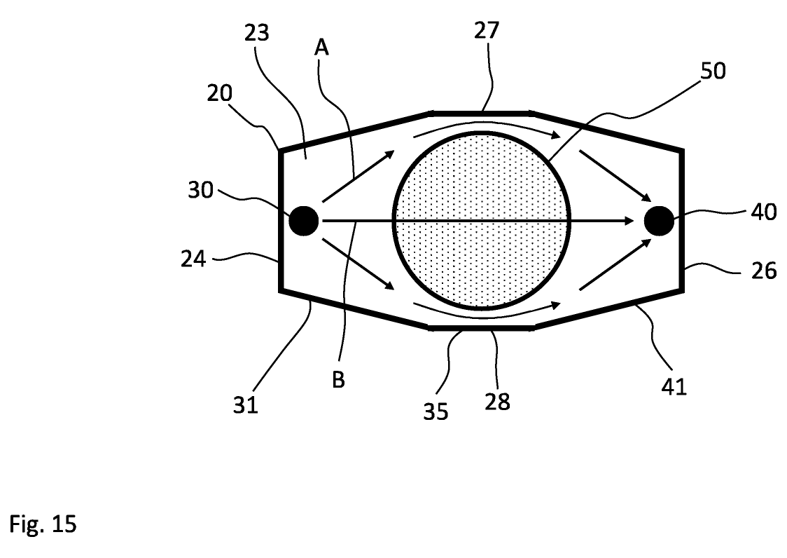

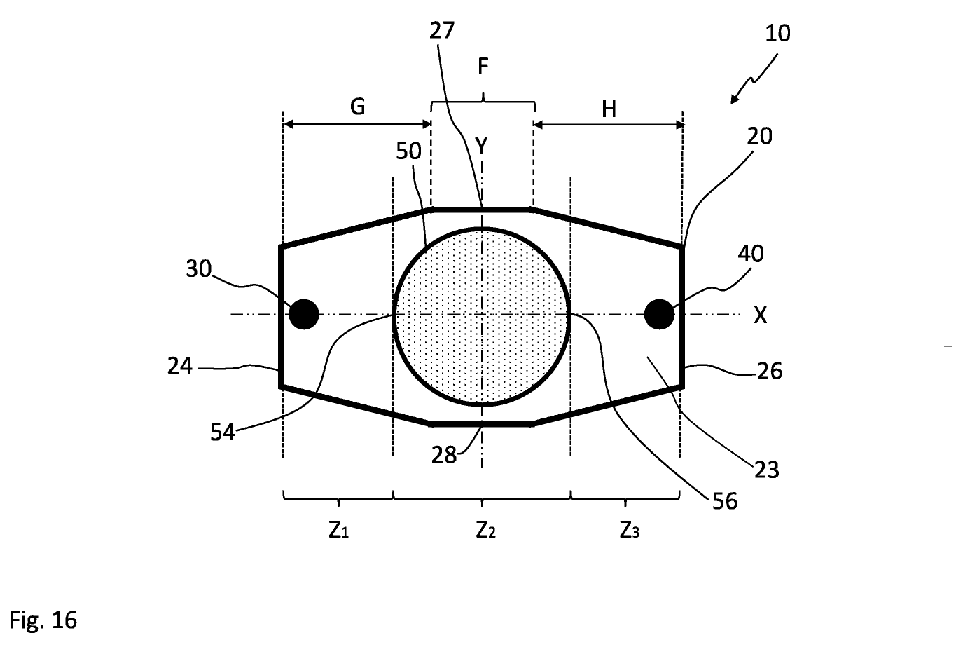

FIGS. 15 and 16 disclose an embodiment which corresponds the embodiment of FIGS. 13 and 14. In the embodiment of FIGS. 15 and 16 the diverging wall portions 31 and the converging wall portions 41 are provided as straight or planar wall portions.

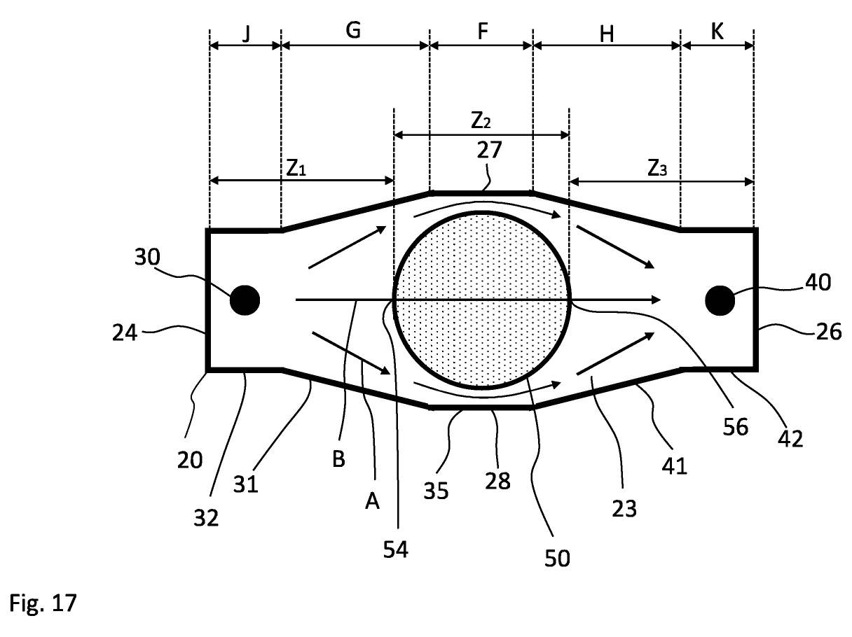

FIG. 17 discloses an embodiment which is a modification of the embodiment of FIGS. 15 and 16.

The embodiment of FIG. 17 comprises a first end constant width area J extending from the first end 24 towards the second end 26 in the direction of the longitudinal central axis X. The first end constant width area J is provided between the first end 24 and the increasing width area G. The first end constant width area J is defined by first end parallel side wall portions 32.

The first end parallel side wall portions 32 extend parallel to the longitudinal central axis X.

As shown in FIG. 17, the gas inlet 30 is arranged to the first end constant width area J. This enables increasing the distance between the gas inlet 30 and the substrate holder 50 or the front end 54.

The first end constant width area J is disposed in the supply zone Z₁ of the reaction chamber 20.

The substrate zone Z₂ and the increasing width area G are partly overlapped in the direction of the longitudinal central axis X. Thus, the substrate zone Z₂ extends to the increasing width area G.

The embodiment of FIG. 17 further comprises a second end constant width area K extending from the second end 26 towards the first end 24 in the direction of the longitudinal central axis X. The second end constant width area K is provided between the second end 26 and the decreasing width area H. The second end constant width area K is defined by second end parallel side wall portions 42.

The second end parallel side wall portions 42 extend parallel to the longitudinal central axis X.

As shown in FIG. 17, the gas outlet 40 is arranged to the second end constant width area K. This enables increasing the distance between the gas outlet 40 and the substrate holder 50 or the back end 56.

The second end constant width area K is disposed in the discharge zone Z₃ of the reaction chamber 20.

The substrate zone Z₂ and the decreasing width area H are partly overlapped in the direction of the longitudinal central axis X. Thus, the substrate zone Z₂ extends to the decreasing width area H.

The constant width area F is arranged within the substrate zone Z2 and between the increasing width area G and the decreasing width area H.

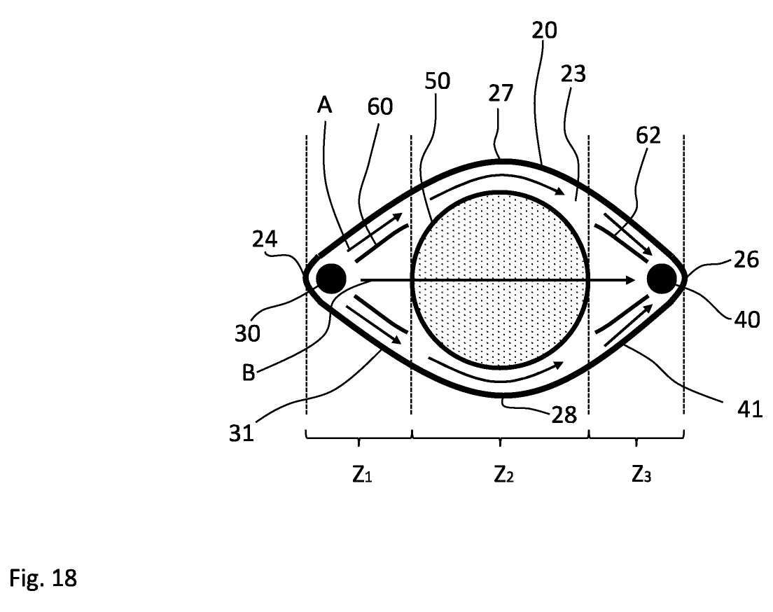

FIG. 18 shows a modification to the embodiment of FIGS. 3 to 6. The reaction chamber 20 is provided with supply flow guides 60 arranged to the supply zone Z₁. The supply flow guides 60 are arranged to guide the gas flow from the gas inlet 30 to the flow path A and flow path B.

The supply flow guides 60 are arranged to the increasing width area G.

The supply flow guides 60 are arranged substantially parallel to the diverging wall portions 31. There is at least one supply flow guide 60 on opposite sides of the longitudinal central axis X.

The reaction chamber 20 is further provided with discharge flow guides 62 arranged to the discharge zone Z₃. The discharge flow guides 62 are arranged to guide the gas flow from the flow path A and flow path B to the gas outlet 40.

The discharge flow guides 62 are arranged to the decreasing width area H.

The discharge flow guides 62 are arranged substantially parallel to the converging wall portions 41. There is at least one discharge flow guide 62 on opposite sides of the longitudinal central axis X.

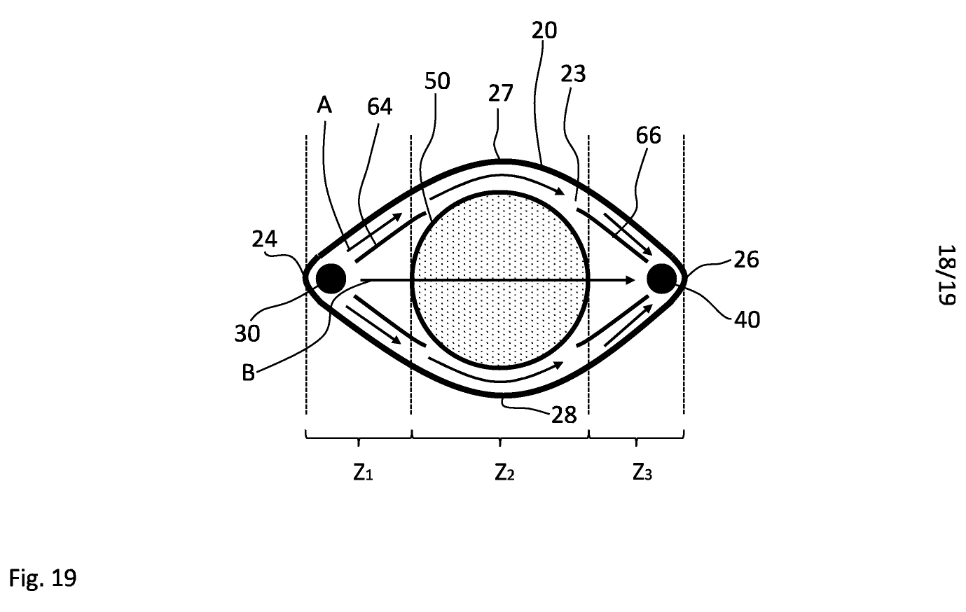

FIG. 19 shows a further modification to the embodiment of FIGS. 3 to 6. The reaction chamber 20 is provided with supply flow guides 60 arranged to extend from the supply zone Z₁ to the substrate zone Z₂. The supply flow guides 60 are arranged to guide the gas flow from the gas inlet 30 to the flow path A and flow path B.

The supply flow guides 60 are arranged to the increasing width area G.

The supply flow guides 60 are arranged substantially parallel to the diverging wall portions 31. There is at least one supply flow guide 60 on opposite sides of the longitudinal central axis X.

The reaction chamber 20 is further provided with discharge flow guides 62 arranged to extend from the discharge zone Z₃ to the substrate zone Z₂. The discharge flow guides 62 are arranged to guide the gas flow from the flow path A and flow path B to the gas outlet 40.

The discharge flow guides 62 are arranged to the decreasing width area H.

The discharge flow guides 62 are arranged substantially parallel to the converging wall portions 41. There is at least one discharge flow guide 62 on opposite sides of the longitudinal central axis X.

In some embodiments, the discharge flow guides 62 may be omitted and there are only supply flow guides 60.

The supply flow guides 60 and the discharge flow guides 62 are plates or vanes.

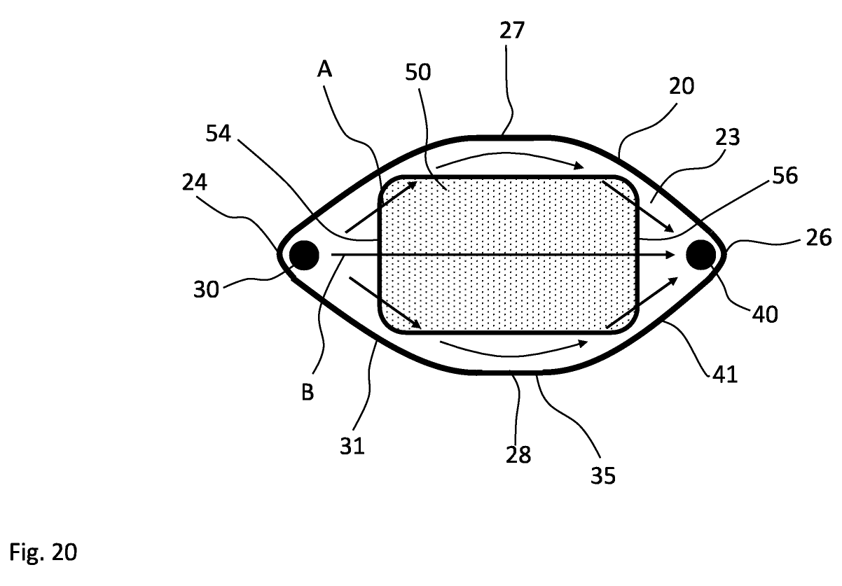

FIG. 20 shows a modification of the embodiment of FIGS. 13 and 14. In the embodiment of FIG. 20, the reaction chamber 20 has generally oval or oval-like shape.

There is a longitudinal substrate holder 50 in the reaction chamber 20 arranged between the first end 24 and the second end 26, or more specifically between the gas inlet 30 and the gas outlet 40. The substrate holder 50 is arranged to hold one or more substrates, especially circular substrates during processing.

The longitudinal substrate holder 50 is arranged to hold or support two or more substrates, such as circular substrates, successively or in a row between the gas inlet 30 and the gas outlet 40. The successive substrates are arranged at the same level or height from the bottom wall 23 of the reaction chamber 20. The longitudinal substrate holder 50 may also be arranged to hold or support two or more substrates on top of each other, as shown on FIGS. 7 and 8.

The longitudinal substrate holder 50 is arranged between the first and second ends 24, 26, and between the gas inlet 30 and the gas outlet 40.

Preferably, the longitudinal substrate holder 50 is arranged in the center of the reaction chamber 20, in the cross section of the longitudinal central axis X and the width central axis Y.

The longitudinal substrate holder 50 extends from the increasing width area G to the decreasing width area H via the constant width area F.

In an alternative embodiment, the constant width area F may be omitted and the longitudinal substrate holder 50 extends from the increasing width area G to the decreasing width area H.

The disclosure has been described above with reference to the examples shown in the figures. However, the disclosure is not limited to the above examples and may vary within the scope of the claims.

What is claimed is:

1. An atomic layer deposition reaction chamber, comprising:
a first end;
a second end opposite the first end;
a longitudinal central axis extending between the first end and the second end;
a length between the first end and the second end in a direction of the longitudinal central axis;
a first side wall extending between the first end and the second end;
a second side wall opposite the first side wall and extending between the first end and the second end, the first side wall and the second side wall defining a width of the reaction chamber between the first end and the second end;
a width central axis extending between the first side wall and the second side wall and perpendicular to the longitudinal central axis;
a gas inlet configured to supply gas into the reaction chamber; and
a gas outlet configured to discharge gas from the reaction chamber,
wherein the gas inlet and the gas outlet are spaced apart from one another along the longitudinal central axis,
wherein the reaction chamber comprises an increasing width area between the first end and the width central axis, the width of the reaction chamber in the increasing width area increasing along the longitudinal central axis in a direction from the first end toward the width central axis,
wherein the reaction chamber comprises a decreasing width area between the width central axis and the second end, the width of the reaction chamber in the decreasing width area decreasing along the longitudinal central axis in a direction from the width central axis toward the second end,
wherein the reaction chamber comprises a constant width area between the increasing width area and the decreasing width area, the width of the reaction chamber in the constant width area being constant along the longitudinal central axis, and
wherein the length of the reaction chamber is greater than the width of the reaction chamber along the width central axis.

2. The atomic layer deposition reaction chamber of claim 1, further comprising a substrate holder arranged inside the reaction chamber between the first end and the second end and between the gas inlet and the gas outlet.

3. The atomic layer deposition reaction chamber of claim 2, wherein the substrate holder is arranged symmetrically inside the reaction chamber with respect to an intersection of the longitudinal central axis and the width central axis.

4. The atomic layer deposition reaction chamber of claim 2, wherein the substrate holder extends in the direction of the longitudinal central axis in the increasing width area and in the decreasing width area.

5. The atomic layer deposition reaction chamber of claim 2, wherein the substrate holder extends in the direction of the longitudinal central axis from the increasing width area to the decreasing width area.

6. The atomic layer deposition reaction chamber of claim 2, wherein the substrate holder extends in the direction of the longitudinal central axis in the increasing width area, in the decreasing width area, and in the constant width area.

7. The atomic layer deposition reaction chamber of claim 2, wherein the substrate holder extends in the direction of the longitudinal central axis from the increasing width area to the decreasing width area through the constant width area.

8. The atomic layer deposition reaction chamber of claim 2, wherein:
the substrate holder comprises, in the direction of the longitudinal central axis, a front end facing the first end and a back end facing the second end;
the substrate holder defines a substrate zone inside the reaction chamber between the front end of the substrate holder and the back end of the substrate holder in the direction of the longitudinal central axis;
the reaction chamber further comprises a supply zone extending in the direction of the longitudinal central axis between the first end of the reaction chamber and the front end of the substrate holder, the gas inlet being disposed in the supply zone;
the reaction chamber further comprises a discharge zone extending in the direction of the longitudinal central axis between the second end of the reaction chamber and the back end of the substrate holder, the gas outlet being disposed in the discharge zone;
the increasing width area extends in the direction of the longitudinal central axis from the supply zone to the substrate zone; and
the decreasing width area extends in the direction of the longitudinal central axis from the discharge zone to the substrate zone.

9. The atomic layer deposition reaction chamber of claim 8, wherein the constant width area is disposed within the substrate zone in the direction of the longitudinal central axis.

10. The atomic layer deposition reaction chamber of claim 9, wherein the substrate zone has a length in the direction of the longitudinal central axis that is greater than a length of the constant width area in the direction of the longitudinal central axis.

11. The atomic layer deposition reaction chamber of claim 2, wherein a first distance between the substrate holder and the first side wall along the width central axis is smaller than a second distance between the substrate holder and the first end along the longitudinal central axis.

12. The atomic layer deposition reaction chamber of claim 11, wherein a third distance between the substrate holder and the second side wall along the width central axis is smaller than a fourth distance between the substrate holder and the second end along the longitudinal central axis.

13. The atomic layer deposition reaction chamber of claim 2, wherein the substrate holder is configured to support one or more circular substrates.

14. The atomic layer deposition reaction chamber of claim 13, wherein the one or more circular substrates comprise one or more circular semiconductor wafers.

15. The atomic layer deposition reaction chamber of claim 1, wherein the reaction chamber further comprises a bottom wall and a top wall, and wherein the first side wall, the second side wall, the first end, and the second end extend between the bottom wall and the top wall.

16. The atomic layer deposition reaction chamber of claim 15, wherein the gas inlet and the gas outlet are disposed in the bottom wall.

17. The atomic layer deposition reaction chamber of claim 16, wherein the gas inlet is disposed in the bottom wall adjacent the first end, and wherein the gas outlet is disposed in the bottom wall adjacent the second end.

18. An atomic layer deposition reactor, comprising:
a vacuum chamber; and
a reaction chamber arranged inside the vacuum chamber, the reaction chamber comprising:
a first end,
a second end opposite the first end,
a longitudinal central axis extending between the first end and the second end,
a length between the first end and the second end along the longitudinal central axis,
a first side wall extending between the first end and the second end,
a second side wall opposite the first side wall and extending between the first end and the second end,
a width central axis extending between the first side wall and the second side wall and perpendicular to the longitudinal central axis,
a width between the first side wall and the second side wall in a direction of the width central axis,
a gas inlet configured to supply gas into the reaction chamber, and
a gas outlet configured to discharge gas from the reaction chamber,
wherein the gas inlet and the gas outlet are spaced apart from one another on opposite sides of the width central axis along the longitudinal central axis,
wherein the first side wall and the second side wall define an increasing width area in which the width of the reaction chamber increases along the longitudinal central axis in a direction from the gas inlet toward the width central axis,
wherein the first side wall and the second side wall define a decreasing width area in which the width of the reaction chamber decreases along the longitudinal central axis in a direction from the width central axis toward the gas outlet,
wherein the first side wall and the second side wall define a constant width area between the increasing width area and the decreasing width area, the width of the reaction chamber in the constant width area being constant along the longitudinal central axis, and
wherein the length of the reaction chamber is greater than the width of the reaction chamber along the width central axis.

19. The atomic layer deposition reactor of claim 18, further comprising at least one gas inlet connection extending from outside the vacuum chamber to the reaction chamber and connected to the gas inlet, the at least one gas inlet connection being configured to supply gas into the reaction chamber from outside the vacuum chamber.

20. The atomic layer deposition reactor of claim 19, further comprising at least one gas outlet connection extending from outside the vacuum chamber to the reaction chamber and connected to the gas outlet, the at least one gas outlet connection being configured to discharge gas from the reaction chamber to outside the vacuum chamber.
